(19) United States
(12) Patent Application Publication
(10) Pub. No.: US 2002/0196094 A1
(43) Pub. Date: Dec. 26, 2002

(54) Method and apparatus for reducing electromagnetic leakage through chassis apertures

(76) Inventors: Harry G. Skinner, Beaverton, OR (US); Scott Noble, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/893,190

(22) Filed: Jun. 26, 2001

(51) Int. Cl. H03H 7/00

(52) U.S. Cl. 333/12; 174/35 GC

(57) ABSTRACT

A method and apparatus for providing ventilation and EMI containment for a computer with at least one plate having a thickness and at least one hole formed therein which substantially coincides with at least one hole formed in a computer chassis to create a waveguide effect.

### FIELD OF THE INVENTION

This invention relates generally to computers, and more particularly to ventilation and electromagnetic interference containment.

### BACKGROUND

As computer clock speeds increase, the amount of heat and electromagnetic interference (“EMI”) generated increases as well. As such, the trend is to make ventilation holes in the computer chassis smaller, in order to protect against excessive EMI radiation. However, the smaller holes have a negative effect on the ability of the chassis to provide ventilation. Thus, it is more likely that the internal components may overheat.

In order to address this problem, waveguide techniques have been used to provide ventilation and EMI protection. Some examples of this include waveguides with a honeycomb or mesh design. However, conventional waveguides can get clogged with dust, lint, or other particles. In addition, conventional waveguides are sensitive and susceptible to damage. Moreover, conventional waveguides can be expensive (e.g., ranging from $1 to $4). In addition, the shipping charges required to transport such a waveguide can be relatively high. Furthermore, conventional waveguides do not create a clear upgrade path since the designer must change the production process to include adaptation of the chassis, making the additional component, and providing for attachment of the component to the chassis.

Failure to provide a clear upgrade path can be expensive since it is not unusual for a chassis design to cost between $300,000 to $1,000,000 in tooling expenses. Hopefully, a chassis design would have a lifetime of at least three years. However, as clock speeds increase, EMI also increases, which may require a redesign of a chassis, including retooling expenses. Furthermore, a redesign requires an additional investment of time. Alternatively, end users may buy an additional EMI protection device, which can be costly as discussed above.

### DESCRIPTION OF THE DRAWINGS

Various embodiments are illustrated by way of example and not by way of limitation in the figures of the accompanying drawings in which like references indicate similar elements. It should be noted that references to “an”? or “one” embodiment in this disclosure are not necessarily to the same embodiment, and such references mean at least one.

FIG. 1 is a front plan view of a plate in accordance with one embodiment.

FIG. 2 is an exploded perspective view of two thin plates screwed together with a computer chassis located between the two plates.

FIG. 3 is a cross-section of FIG. 2 showing how the plates are screwed together.

FIG. 4 is an exploded perspective view of one thick plate screwed to a computer chassis.

FIG. 5 is a cross-section of FIG. 4 showing how the plate is screwed on to the computer chassis.

### DETAILED DESCRIPTION

The various embodiments described herein overcome problems in the existing art described above by providing a method and apparatus to contain EMI radiation and maintain adequate ventilation at only a fraction of the cost of current waveguides. Moreover, the various embodiments need not be planned for or designed in advance, which saves additional time and money. In the following description, for purposes of explanation, numerous specific details are set forth in order to provide a thorough understanding of the various embodiments. It will be apparent, however, to one skilled in the art that the various embodiments may be practiced without some of the specific details. The following description and the accompanying drawings provide examples for the purposes of illustration only. However, these examples should not be construed in a limiting sense as they are merely intended to provide exemplary embodiments, rather than to provide an exhaustive list of all possible implementations.

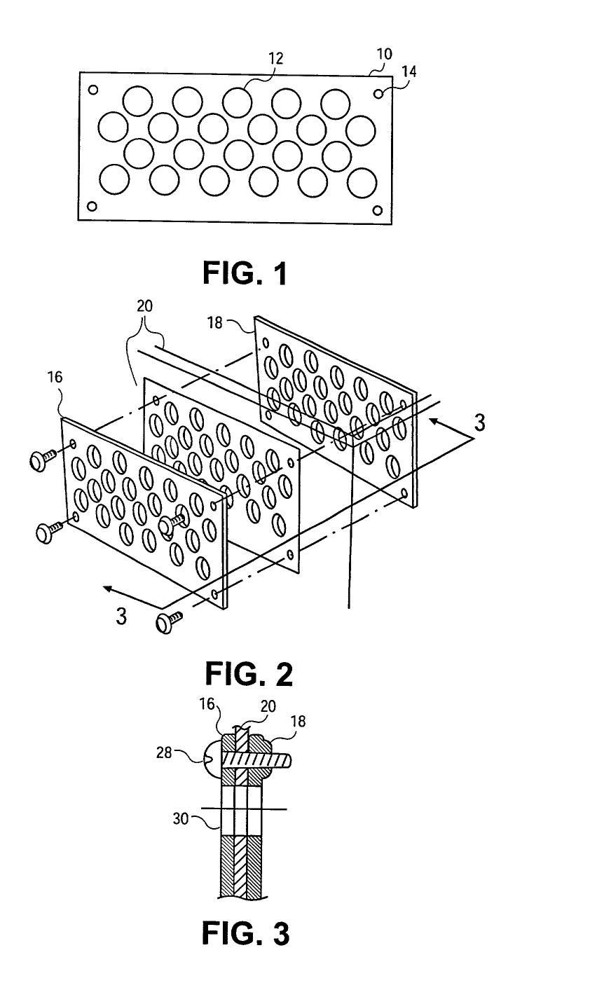

Referring now to FIG. 1, a single plate 10, in accordance with an embodiment, is shown. The plate has holes 12 for ventilation and screw holes 14 for attachment of the plate to a computer chassis. It is worth noting that the holes 12 are designed to coincide with holes formed in a computer chassis. Although the holes 12 are circular, in other embodiments, the holes can have different shapes depending on the need for ventilation and EMI protection for each computer.

Turning now to FIG. 2, another embodiment is shown in which two plates are connected on opposite sides of a computer chassis 20. First plate 18 is connected to the inside of the computer chassis 20, and second plate 16 is connected to the outside of the computer chassis 20. As can be seen, the holes of plate 18 and plate 16 are designed to substantially coincide with the holes formed in computer chassis 20. This creates a waveguide effect to provide airflow and EMI protection. Although plates 18 and 16 are shown on opposite sides of the computer chassis 20, in other embodiments, the plates 16 and 18 may be on the same side or multiple plates may be on both sides. This shows the flexibility of the various embodiments since the plate configuration may be adapted to fit the needs of each computer.

Referring now to FIG. 3, a cross-sectional view of the connection of plates 16 and 18 to computer chassis 20 in FIG. 2 is shown. Specifically, plate 16 is fastened to computer chassis 20 with plate 18 attached on the opposite side of computer chassis 20 by screw 28. Once fully assembled, the holes of first plate 18, computer chassis 20, and second plate 16 substantially coincide to create hole 30. Likewise, the remainder of the holes of plates 16 and 18 and computer chassis 20 substantially coincide to create a waveguide.

It is worth noting that although FIGS. 2 and 3 both use a screw to attach the plate to the computer chassis, other means of attachment are within the contemplation of the various embodiments. For instance, the method of attachment could be a snap, a screw, a rivet, a pivot, or a hinge, or any combination thereof. As mentioned above, a plate may be attached to either the inside or the outside of the computer chassis or both. In addition, multiple plates may be used on both sides or multiple plates may be used on one side of the computer chassis.

In various embodiments, the plates comprise an electrically conductive material. For instance, the plate could be comprised of sheet metal, which is typically electrogalvanized steel, or plastic which is suitable to be plated with a conductive metal. Furthermore, the plate can include a border area without holes to prevent EMI leakage around the edges of the plate. In addition, an electrically conductive gasket can be disposed between the plate and the computer chassis to further decrease the likelihood of EMI leakage.

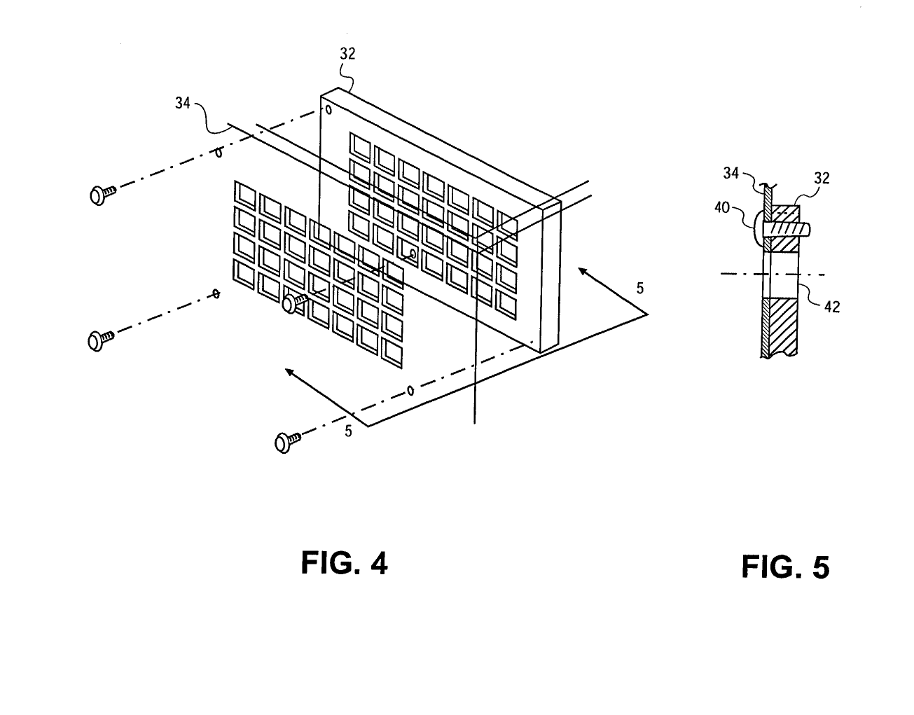

Referring now to FIG. 4, another embodiment is shown in which a thicker plate 32 is used rather than thin plates as in FIG. 2. Thick plate 32 is attached to the inside of computer chassis 34. Again, the holes of thick plate 32 are designed to substantially coincide with the holes of computer chassis 34.

Turning now to FIG. 5, a cross-section of FIG. 4 is shown in which thick plate 32 is mounted to the computer chassis 34 with screw 40, such that the holes of thick plate 32 and computer chassis 34 coincide to create hole 42.

It is to be understood that even though numerous characteristics and advantages of various embodiments have been set forth in the foregoing description, together with details of the structure and function of the various embodiments, this disclosure is illustrative only. Changes may be made in detail, especially matters of structure and management of parts, without departing from the scope of the various embodiments as expressed by the broad general meaning of the terms of the appended claims.

We claim:

1. An apparatus comprising:
at least one plate having a thickness and at least one hole formed therein which substantially coincides with at least one hole formed in a computer chassis to create a waveguide effect.

2. The apparatus of claim 1, wherein the plate is adapted to be coupled to the computer chassis with at least one of a snap, a screw, a rivet, a pivot, and a hinge.

3. The apparatus of claim 1, wherein the plate is adapted to be disposed on at least one of an inside of the computer chassis and an outside of the computer chassis.

4. The apparatus of claim 3, wherein a plurality of plates are adapted to be disposed on the inside of the computer chassis.

5. The apparatus of claim 3, wherein a plurality of plates are adapted to be disposed on the outside of the computer chassis.

6. The apparatus of claim 3, wherein at least one plate is adapted to be disposed on the inside of the computer chassis and at least one plate is adapted to be disposed on the outside of the computer chassis.

7. The apparatus of claim 1, wherein the plate comprises an electrically conductive material.

8. The apparatus of claim 7, wherein the plate comprises at least one of metal and plastic plated with metal.

9. The apparatus of claim 1, wherein the plate includes a border area without holes.

10. The apparatus of claim 1, wherein an electrically conductive gasket is adapted to be disposed between the plate and the computer chassis.

11. An apparatus comprising:
a computer chassis with at least one hole formed therein; and
at least one plate coupled to the computer chassis, the plate having a thickness and at least one hole formed therein which substantially coincides with the holes formed in the computer chassis to create a waveguide effect.

12. The apparatus of claim 11, wherein the plate is coupled to the computer chassis with at least one of a snap, a screw, a rivet, a pivot, and a hinge.

13. The apparatus of claim 11, wherein the plate is disposed on at least one of an inside of the computer chassis and an outside of the computer chassis.

14. The apparatus of claim 13, wherein a plurality of plates are disposed on the inside of the computer chassis.

15. The apparatus of claim 13, wherein a plurality of plates are disposed on the outside of the computer chassis.

16. The apparatus of claim 13, wherein at least one plate is disposed on the inside of the computer chassis and at least one plate is disposed on the outside of the computer chassis.

17. The apparatus of claim 11, wherein the plate comprises an electrically conductive material.

18. The apparatus of claim 17, wherein the plate comprises at least one of metal and plastic plated with metal.

19. The apparatus of claim 11, wherein the plate includes a border area without holes.

20. The apparatus of claim 11, wherein an electrically conductive gasket is disposed between the plate and the computer chassis.

21. A method comprising:
aligning at least one plate having a thickness and at least one hole formed therein such that the hole substantially coincides with at least one hole formed in a computer chassis to create a waveguide effect; and
attaching the plate to the computer chassis.

22. The method of claim 21, wherein attaching includes coupling the plate to the computer chassis with at least one of a snap, a screw, a rivet, a pivot, and a hinge.

23. The method of claim 21, wherein attaching includes disposing the plate on at least one of an inside of the computer chassis and an outside of the computer chassis.

24. The method of claim 23, wherein attaching includes disposing a plurality of plates on the inside of the computer chassis.

25. The method of claim 23, wherein attaching includes disposing a plurality of plates on the outside of the computer chassis.

26. The method of claim 23, wherein attaching includes disposing at least one plate on the inside of the computer chassis and at least one plate on the outside of the computer chassis.

27. The method of claim 21, wherein attaching includes disposing an electrically conductive gasket between the plate and the computer chassis.

28. A method comprising:
creating a hole pattern to substantially coincide with at least one hole formed in a computer chassis; and
forming holes in a plate having a thickness, the holes matching the created hole pattern.

29. The method of claim 28, wherein forming comprises at least one of stamping and drilling holes in the plate.

30. The method of claim 28, wherein forming comprises molding a material into a plate with holes therein.
